(19) United States
(12) Patent Application Publication
(10) Pub. No.: US 2004/0123805 A1
(43) Pub. Date: Jul. 1, 2004

(54) Vacuum treatment method and vacuum treatment device

(76) Inventor: Riki Tomoyoshi, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/475,857

(22) PCT Filed: May 1, 2002
(86) PCT No.: PCT/JP02/04367

(30) Foreign Application Priority Data
May 2, 2001 (JP) 2001-135012

(51) Int. Cl. C23F 1/00; C23C 16/00

(52) U.S. Cl. 118/728; 118/724

(57) ABSTRACT

A vacuum treatment method, which controls work to a target temperature and applies a vacuum treatment thereto, comprising the steps of placing work on a temperature-adjustable table in a vacuum treatment chamber, and feeding thermal conductivity gas into between the table and the work to impart thermal conductivity. The gas feeding step comprises the steps of individually discharging thermal conductivity gases from the respective gas sources of at least two thermal conductivity gases of different thermal conductivities at predetermined flow rates, individually detecting the pressures of the thermal conductivity gases, and individually controlling the thermal conductivity gas feed flow rates on the basis of the detected pressures.

### FIELD OF THE INVENTION

The present invention relates to a vacuum processing method and a vacuum processing device; and, more particularly, to a vacuum processing method and a vacuum processing device capable of carrying out a stable processing at a high vacuum level and a high temperature; rapidly adjusting a processing temperature (target temperature); and controlling the target temperature over a wide range.

### BACKGROUND OF THE INVENTION

A conventional vacuum processing device includes a vacuum processing chamber for carrying out a vacuum processing on an object to be processed, such as a wafer; a temperature-adjustable mounting table installed in the vacuum processing chamber for loading thereon the object to be processed; and a plasma generation unit for generating plasma in order to carry out a predetermined vacuum processing on the object to be processed on the mounting table. Plasma is generated in the vacuum processing chamber by the plasma generation unit and a plasma processing such as etching and film deposition is performed on the object to be processed that is kept at a target temperature by the mounting table.

Herein, a narrow gap may exist between the mounting table and the object to be processed. The gap may serve as a vacuum insulating layer obstructing heat conduction therebetween. Thus, a thermally conductive gas is supplied into the gap between the mounting table and the object to be processed as a backgas in order to improve a thermal conductivity therebetween, so that the temperature of the object to be processed can be efficiently controlled. Widely employed as a thermally conductive gas is, for example, helium exhibiting an excellent thermal conductivity.

Recently, in a process for obtaining, for example, a deep trench structure as shown in FIG. 5, etching is executed at a high temperature (higher than, e.g., about 120° C.). In case of controlling the object to be processed at a high temperature, a pressure of helium gas is reduced down to, e.g., about 3 to 5 torr to reduce a thermal conductivity between the mounting table and the object to be processed while the temperature of the object to be processed is increased by heat from the plasma.

However, as semiconductor devices are getting smaller, it becomes difficult to carry out temperature control for the production of a groove shape, such as a deep trench structure as required in specifications. Especially, in the deep trench process, for example, it is required to reduce the thermal conductivity by lowering a pressure of helium gas as described above. However, in case the helium gas is supplied as the backgas within such a low pressure range as mentioned above, it becomes difficult to maintain the object to be processed at the target temperature due to a poor temperature stability of the object, which in turn makes it very difficult to control the shape of the deep trench structure, and the like.

Further, in case of forming a taper portion T₁ and a perpendicular groove portion T₂, as shown in FIG. 5, by a step etching, a target temperature needs to be rapidly adjusted to properly respond to changes in the shape of a trench T. However, the poor temperature stability of the helium gas under a low pressure may impede a rapid change of the target temperature.

U.S. Pat. No. 2,635,153 discloses an invention for improving a thermal conductivity by using a mixture gas of thermally conductive gases of different thermal conductivities. However, in this invention, it is difficult to precisely control a mixing ratio of the thermally conductive gases.

### SUMMARY OF THE INVENTION

It is, therefore, an object of the present invention to provide a vacuum processing method and a vacuum processing device capable of performing a stable processing on an object to be processed at a high vacuum level and a high temperature and rapidly changing a target temperature.

In accordance with the invention, there is provided a vacuum processing method including the steps of: mounting an object to be processed on a temperature-adjustable mounting table in a vacuum processing chamber; supplying thermally conductive gases between the mounting table and the object to impart a thermal conductivity therebetween; and performing a vacuum processing by controlling the object to be maintained at a target temperature, wherein the gas supplying step includes the steps of: individually discharging at least two species of thermally conductive gases of different thermal conductivities at respective flow rates from respective gas sources thereof; individually detecting a pressure of each of the thermally conductive gases; and individually controlling a feed flow rate of each of the thermally conductive gases based on the detected pressure.

Preferably, the step of individually controlling the feed flow rate has the step of directly controlling the feed flow rate of each of the thermally conductive gases emitted from the gas sources.

Or, preferably, the step of individually controlling the feed flow rate has the step of controlling a degree of openness of a valve installed at a gas pipe.

Further, in accordance with the invention, there is provided a vacuum processing method including the steps of: mounting an object to be processed on a temperature-adjustable mounting table in a vacuum processing chamber; supplying thermally conductive gases between the mounting table and the object to impart a thermal conductivity therebetween; and performing a vacuum processing by controlling the object to be maintained at a target temperature, wherein in the gas supply step, at least two species of thermally conductive gases of different thermal conductivities are individually discharged from respective gas sources thereof; a thermally conductive gas of a relatively higher thermal conductivity is supplied in case where the target temperature of the object is at a side of an initial temperature of the mounting table with respect to an initial temperature of the object; and a thermally conductive gas of a relatively lower thermal conductivity is supplied or a supply of the thermally conductive gases are stopped in case where the target temperature of the object is at an opposite side of an initial temperature of the mounting table with respect to an initial temperature of the object.

Further, in accordance with the invention, there is provided a vacuum processing method including the steps of: mounting an object to be processed on a temperature-adjustable mounting table in a vacuum processing chamber; supplying thermally conductive gases between the mounting table and the object to impart a thermal conductivity therebetween; and performing a vacuum processing by controlling the object to be maintained at a target temperature, wherein, if the temperature of the object reaches the target temperature, the gas supply step includes the steps of: individually discharging at least two species of thermally conductive gases of different thermal conductivities at respective flow rates from gas respective sources thereof; individually detecting a pressure of each of the thermally conductive gas; and individually controlling a feed flow rate of each of the thermally conductive gases based on the target temperature and the detected pressure.

Preferably, when the target temperature is changed in the step of individually controlling the feed flow rate, a flow rate of a thermally conductive gas of a relatively higher thermal conductivity among the thermally conductive gases is increased or turned on in case where the target temperature after change is at a side of a temperature of the mounting table with respect to the target temperature before change; and a flow rate of a thermally conductive gas of a relatively lower thermal conductivity among the thermally conductive gases is increased or turned on or a supply of the thermally conductive gases is ceased in case where the target temperature after change is at an opposite side of the temperature of the mounting table with respect to the target temperature before change.

Further, preferably, the method further includes the step of obtaining in advance a first reference flow ratio and a first reference pressure ratio of the thermally conductive gases when the object is maintained at the target temperature and wherein the step of individually controlling the feed flow rate has the step of controlling a total feed amount of the thermally conductive gases while maintaining the first reference flow ratio and the first reference pressure ratio constant.

Or, preferably, the method further includes the step of obtaining in advance a second reference flow ratio and a second reference pressure ratio of the thermally conductive gases when the object is maintained at a constant temperature lower than the target temperature, wherein the step of individually controlling the feed flow rate has the step of increasing and decreasing or turning on and off a flow rate of a thermally conductive gas of a relatively higher thermal conductivity among the thermally conductive gases based on the second reference flow ratio and the second reference pressure ratio.

Or, preferably, the method further includes the step of obtaining in advance a second reference flow ratio and a second reference pressure ratio of the thermally conductive gases when the object is maintained at a constant temperature lower than the target temperature, wherein the step of individually controlling the feed flow rate has the step of increasing and decreasing or turning on and off a flow rate of a thermally conductive gas of a relatively lower thermal conductivity among the thermally conductive gases based on the second reference flow ratio and the second reference pressure ratio.

Or, preferably, the method includes the step of obtaining in advance a third reference flow ratio and a third reference pressure ratio of the thermally conductive gases when the object is maintained at a constant temperature higher than the target temperature, wherein the step of individually controlling the feed flow rate has the step of increasing and decreasing or turning on and off a flow rate of a thermally conductive gas of a relatively lower thermal conductivity among the thermally conductive gases based on the third reference flow ratio and the third reference pressure ratio.

Or, preferably, the method includes the step of obtaining in advance a third reference flow ratio and a third reference pressure ratio of the thermally conductive gases when the object is maintained at a constant temperature higher than the target temperature, wherein the step of individually controlling the feed flow rate has the step of increasing and decreasing or turning on and off a flow rate of a thermally conductive gas of a relatively higher thermal conductivity among the thermally conductive gases based on the third reference flow ratio and the third reference pressure ratio.

In accordance with the invention, there is provided a vacuum processing apparatus including: a vacuum processing chamber; a temperature-adjustable mounting table installed in the vacuum processing chamber; gas sources for respectively discharging at least two species of thermally conductive gases of different thermal conductivities at respective flow rates; a gas channel for supplying the thermally conductive gases discharged from the gas sources between the mounting table and an object mounted thereon; a pressure detecting unit for individually detecting a pressure of each of the thermally conductive gases in the gas channel; and a controller for individually controlling a feed flow rate of each of the thermally conductive gases based on the pressure detected by the pressure detecting unit.

### BRIEF DESCRIPTION OF THE DRAWINGS

FIG. 1 shows a block diagram of a vacuum processing device in accordance with a preferred embodiment of the present invention;

FIG. 2 describes a horizontal cross sectional view illustrating a coolant passageway of a supporting body shown in FIG. 1;

FIG. 3 presents a schematic cross sectional view of a structure of a mounting table shown in FIG. 1;

FIG. 4 offers a plan view of an electrostatic chuck shown in FIG. 3; and

FIG. 5 depicts a cross sectional structure of a deep trench.

### DETAILED DESCRIPTION OF THE PREFERRED EMBODIMENTS

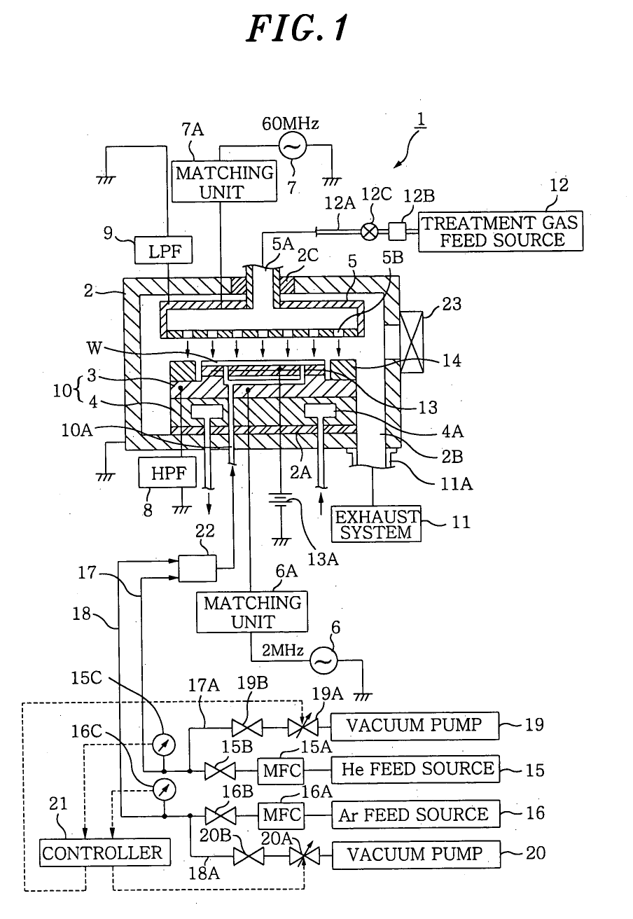

Hereinafter, the present invention will be described with reference to a preferred embodiment thereof shown in FIGS. 1 to 4.

A vacuum processing device 1 shown in FIG. 1 includes a vacuum processing chamber 2 capable of maintaining a desired high vacuum level therein. A surface of the vacuum processing chamber 2 is alimite processed and electrically grounded. Installed at a central lower portion of the vacuum processing chamber 2 is a lower electrode 3 for mounting an object to be processed (e.g., a wafer (W)) thereon. A bottom surface of the lower electrode 3 is supported by a supporting body 4 mounted on the bottom of the vacuum processing chamber 2 via an insulation member 2A. An upper electrode 5 of a hollow shape is disposed above the lower electrode 3 with a gap maintained therebetween. Connected to the lower electrode 3 via a matching unit 6A is a high frequency power supply 6. Connected to the upper electrode 5 via a matching unit 7A is a high frequency power supply 7 for the application of a high frequency higher than that provided from the high frequency power supply 6. Further connected to the lower electrode 3 and the upper electrode 5 are a high pass filter 8 and a low pass filter 9, respectively. Further, a mounting table 10 includes the lower electrode 3 and the supporting body 4.

Formed at the bottom of the vacuum processing chamber 2 is an exhaust opening 2B. Connected to the exhaust opening 2B via a pipe 11A is an exhaust system 11. The exhaust system 11 evacuates the vacuum processing chamber 2 to maintain a desired vacuum level therein. Formed at a center of an upper portion of the upper electrode 5 is a gas inlet duct 5A which passes through an insulation member 2C disposed at a center of an upper portion of the vacuum processing chamber 2. Connected to the gas inlet duct 5A via a pipe 12A is a processing gas feed source 12. Successively installed in downstream of the pipe 12A from the processing gas feed source 12 are a mass flow controller 12B and a valve 12C through which a flow rate of a processing gas supplied into the vacuum processing chamber 2 is controlled. Uniformly provided at a bottom of the upper electrode 5 is a plurality of holes 5B through which the processing gas is supplied into the vacuum processing chamber 2 while being uniformly dispersed. Therefore, if a high frequency power is applied to each of the lower electrode 3 and the upper electrode 5 while the vacuum processing chamber 2 is evacuated in vacuum by the exhaust system 11 and concurrently the processing gas is provided from the processing gas feed source 12 at a predetermined flow rate, a plasma of the processing gas is generated in the vacuum processing chamber 2, so that a preset plasma processing (for example, etching) is carried out on the wafer W placed on the mounting table 10. Installed on the mounting table 10 is a temperature sensor (not shown), which constantly monitors the temperature of the wafer W on the mounting table 10.

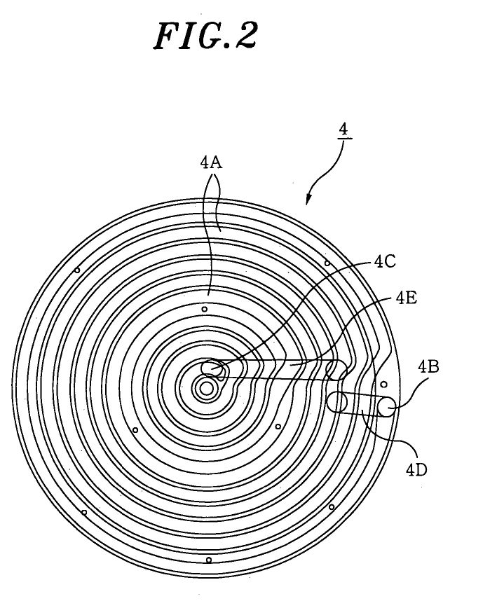

Formed in the supporting body 4 is a coolant passageway 4A through which a coolant (for example, a known fluorine based fluid, water, or the like) flows to cool the lower electrode 3. The wafer W is also cooled through the lower electrode 3, so that the wafer W can be controlled to obtain a desired temperature. In FIG. 1, an inlet port and an outlet port of the coolant passageway 4A are drawn to be spaced apart from each other. Alternatively, as exemplified in FIG. 2, an inlet port 4B of the coolant passageway 4A may be formed at an outer circumferential region of the supporting body 4 while an outlet port 4C thereof may be formed at a location which slightly deviates from the center of the supporting body 4. In such a case, a passageway longer than 2 meters can be spirally formed from the inlet port 4B to the outlet port 4C. In the exemplary case illustrated in FIG. 2, a coolant inlet tube 4D and a coolant outlet tube 4E disposed close to each other are installed in a substantially vertical direction from a region below an outer peripheral portion of the supporting body 4 up to a bottom surface thereof. Further, an upper end portion of the inlet tube 4D and an upper end portion of the outlet tube 4E are extended to the inlet port 4B and the outlet port 4C along the bottom of the supporting body 4, respectively.

A coolant having a kinematic viscosity (u=p/p) of, e.g., about 2×10⁻⁶ m²/second (i.e., 2 centistokes) is used. Such coolant can be supplied into the coolant passageway 4A at a flow rate of about 30 L/minute. At this time, Reynolds number (Re=ud/υ) is set to be, e.g., equal to or greater than 3300. Under such conditions, there occurs a turbulent flow of the coolant within the coolant passageway 4A, thereby enhancing a thermal exchange efficiency.

Disposed within the lower electrode 3 is an electrostatic chuck 13, which is connected to a DC power supply 13A. By applying a high voltage to the electrostatic chuck 13 from the DC power supply 13A, the electrostatic chuck 13 can hold the wafer W electrostatically. A focus ring 14 is installed along the circumference of the lower electrode 3 to surround the electrostatic chuck 13. The focus ring 14 allows plasma to converge onto the wafer W.

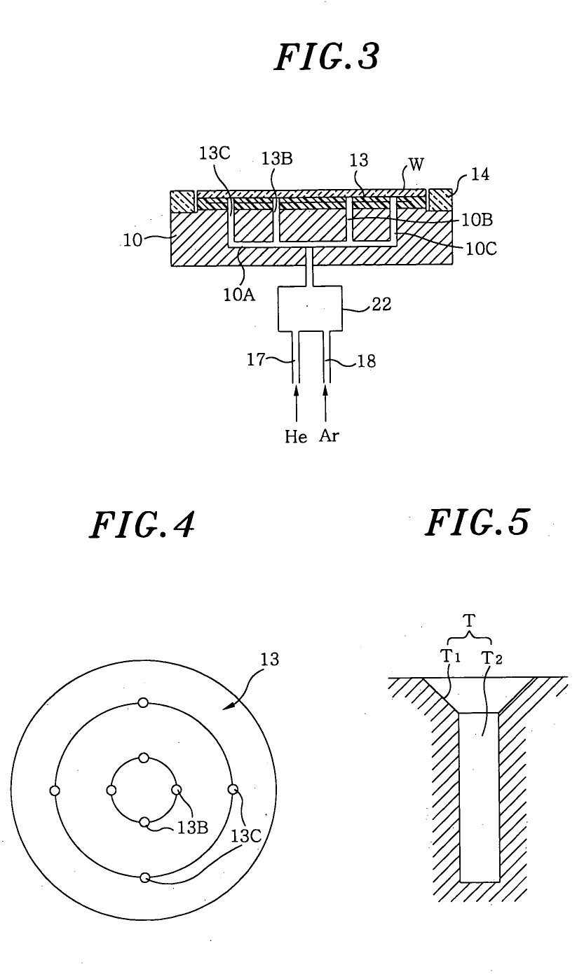

Further formed in the mounting table 10 is a gas channel 10A of a thermally conductive gas. As shown in FIGS. 3 and 4, the gas channel 10A branches off into first and second branch channels 10B and 10C within the mounting table 10 and each of the branch channels 10B and 10C has an open end. More preferably, the branch channels 10B and 10C are respectively installed at an approximately equal interval along the circumferences of two coaxial circular cylinders. Formed in the electrostatic chuck 13 on the mounting table 10 is a multiplicity of first and second through holes 13B and 13C, which coincide with open ends of the branch channels 10B and 10C of the mounting table 10. Therefore, a thermally conductive gas supplied into the gas channel 10A uniformly spreads through the entire gap between the electrostatic chuck 13 and the wafer W via the first and the second branch channel 10B and 10C and the first and second through holes 13B and 13C. Thus, a thermal conductivity in the gap can be increased.

As shown in FIG. 1, connected to the gas channel 10A via gas pipes 17 and 18 are, e.g., a He feed source 15 and an Ar feed source 16, respectively, which serve to supply two kinds of thermally conductive gases, i.e., a thermally conductive gas of a high thermal conductivity (e.g., helium (He) gas) and a thermally conductive gas of a low thermal conductivity (e.g., argon (Ar) gas) into the gas channel 10A.

Successively installed at downstream of the He gas pipe 17 from the He feed source 15 are a mass flow controller (MFC) 15A and a valve 15B. The mass flow controller 15A controls a flow rate of He gas. Connected to the gas pipe 17 via a branch pipe 17A is a vacuum pump 19. An exhaust air volume of the vacuum pump 19 is controlled via a variable valve 19A.

Successively installed at downstream of the Ar gas pipe 18 from the Ar feed source 16 are a mass flow controller (MFC) 16A and a valve 16B. The mass flow controller 16A controls a flow rate of Ar gas. Connected to the gas pipe 18 via a branch pipe 18A is a vacuum pump 20. An exhaust air volume of the vacuum pump 20 is controlled via a variable valve 20A.

Further, installed at the gas pipes 17 and 18 are pressure detecting units 15C and 16C, respectively. The pressure detecting units 15C and 16C detect pressures of the He gas and the Ar gas flowing in the gas pipes 17 and 18, respectively. Both of the pressure detecting units 15C and 16C are connected to a controller 21 via A/D converters (not shown). The controller 21 opens and closes the variable valves 19A and 20A based on the pressure values detected by the pressure detecting units 15C and 16C, so that the pressures of the He gas and the Ar gas can be independently controlled. The controller 21 controls flow rates of the He gas and the Ar gas via the mass flow controller 15A and 16A, respectively. Therefore, the controller 21 can calculate and control a flow ratio and a pressure ratio of the two gases. Further, reference numerals 19B and 20B in FIG. 1 also represent valves.

The gas pipes 17 and 18 are connected to the gas channel 10A via a mixing unit 22 in which the He gas and the Ar gas are uniformly mixed. As a complex thermally conductive gas, the mixture of He and Ar gases is provided into the gap between the electrostatic chuck 13 and the wafer W through the gas channel 10A, the first and second branch channels 10B, 10C, and the first and second through holes 13B, 13C; and then diffuses through the gap to the surroundings of the mounting table 10. Furthermore, if the He gas and the Ar gas can be uniformly mixed in the gas channel 10A, the installation of the mixing unit 22 may not be required. In addition, a reference numeral 23 in FIG. 1 represents a gate valve.

In the preferred embodiment, the flow rates and the pressures of the He gas of a high thermal conductivity and the Ar gas of a low thermal conductivity can be individually controlled independently. Thus, by properly controlling the flow ratio and the pressure ratio of the He gas and the Ar gas as required when supplying these thermally conductive gases into the mounting table 10, a thermal conductivity of the complex thermally conductive gas can be controlled. Accordingly, it is possible to enhance or restrict a cooling capability of the mounting table 10. In case a change of the target temperature is required for, e.g., a step etching or the like, the target temperature can be rapidly changed by controlling the flow ratio and the pressure ratio of the He gas and the Ar gas, accordingly.

Next, a vacuum processing method using the vacuum processing device 1 will be described in accordance with a preferred embodiment of the present invention. The vacuum processing method of the present invention is characterized in that a flow ratio and/or a pressure ratio of plural kinds of thermally conductive gases are appropriately adjusted in a manner adapted to a wafer W processing step. Particularly, the present invention is characterized in that pressures of the plural kinds of thermally conductive gases are respectively detected just prior to being mixed; and a flow rate of each thermally conductive gas is increased or decreased by controlling variable valves based on the detected pressures to thereby accurately control a mixture ratio of the thermally conductive gases included in a complex thermally conductive gas after being mixed; and thus a thermal conductivity of the complex thermally conductive gas can be precisely controlled. Therefore, description of the wafer W processing method will now be described focusing on the control of He gas and Ar gas.

First, a wafer W is loaded into the vacuum processing chamber 2. Specifically, the gate valve 23 is opened and the wafer W is loaded onto the mounting table 10 by a transfer mechanism (not shown). Then the gate valve 23 is closed.

The vacuum processing chamber 2 is evacuated in vacuum by the exhaust system 11 while a processing gas of a predetermined flow rate is supplied into the upper electrode 5 from the processing gas feed source 12. Thus, the processing gas is uniformly diffused in the entire vacuum processing chamber 2 and a pressure within the vacuum processing chamber 2 is maintained at a predetermined vacuum level. In the meantime, a coolant circulates through the coolant passageway 4A within the mounting table 10, thereby controlling a temperature of each of the supporting body 4, the lower electrode 3 and the electrostatic chuck 13 to fall within a range of, for example, from −10 to 70° C.

Further, the He gas and the Ar gas are supplied from the He feed source 15 and the Ar feed source 16 toward the gas channel 10A of the mounting table 10. Then, the He gas and the Ar gas are uniformly mixed in the mixing unit 22 and then supplied as a complex thermally conductive gas into the gap between the electrostatic chuck 13 and the wafer W via the first and second branch channels 10B, 10C and the first and second through holes 13B, 13C. Thus, a thermal conductivity between the electrostatic chuck 13 and the wafer W is controlled, and therefore, heat conduction between the mounting table 10 and the wafer W can be controlled.

At this time, the controller 21 can accurately control the thermal conductivity between the electrostatic chuck 13 and the wafer W by controlling a flow ratio and a pressure ratio for the complex thermally conductive gas. That is, in case of processing the wafer W at a high temperature (for example, 120° C.), the thermal conductivity between the electrostatic chuck 13 and the wafer W is controlled to be reduced or intermittently set as zero (i.e., insulated), if necessary. Accordingly, heat conduction to the electrostatic chuck 13 from the wafer W whose temperature is raised by a plasma processing is limited, so that the wafer W is stabilized at the high temperature. On the other hand, in case of processing the wafer W at a low temperature close to the temperature of the mounting table 10, a thermal conductivity between the electrostatic chuck 13 and the wafer W is controlled to increase. Accordingly, the heat conduction from the wafer W to the electrostatic chuck 13 is facilitated, so that the wafer W can be efficiently cooled.

If high frequency powers are applied to the upper and the lower electrode 3 and 5 with the flow ratio and the pressure ratio of the complex thermally conductive gas controlled, plasma is generated between the electrodes 3 and 5. Accordingly, a predetermined plasma processing such as a step etching can be performed on the wafer W placed on the mounting table 10 while a predetermined processing temperature (a target temperature) of the wafer W is being maintained. After the plasma processing is completed, the wafer W is taken out of the vacuum processing chamber 2 in a reverse order of the wafer loading process.

In processing the wafer W in accordance with the preferred embodiment, a flow ratio and a pressure ratio of the He gas and the Ar gas are adaptively controlled at varying processing stages (for example, when loading a wafer, when a step in which the wafer W reaching a target temperature, and when changing the target temperature).

A flow ratio and a pressure ratio of the two gases at each stage are obtained in advance by simulating conditions equal to an actual process (simulation) or by actually processing the wafer W under conditions same as in the actual process. Thus obtained flow ratio and pressure ratio for each stage are pre-registered as a reference flow ratio and a reference pressure ratio in a memory (not shown) of the controller 21. To be more specific, the reference flow and pressure ratios are obtained as follows. Before supplying the He and Ar gases, flow rates of He gas and Ar gas are preset in the mass flow controllers 15A and 16A, respectively, for each actual process for the wafer W. Then, the He gas and the Ar gas are supplied in each process wherein the flow rates of the gases are independently controlled based on their corresponding preset flow rates. After completing the flow rate control, pressures of the two gases are individually detected by the pressure detecting units 15C and 16C, and a temperature of the wafer W at the moment is also detected. If the wafer W reaches a target temperature or thereabout and is maintained thereat, the flow rates and the pressures of the two gases at each temperature are registered in the controller 21 as reference flow rates and reference pressures. Also, a reference flow ratio and a reference pressure ratio of the two gases at each temperature are registered therein as well.

Thereafter, the flow rates and the pressures of the two gases are controlled based on these reference values. Therefore, a thermal conductivity of the backside of the wafer W is controlled, so that the temperature of the wafer W is more properly controlled. At this time, a temperature requirement specified in the following expression should be satisfied. In the following expression, t₁ is defined as a temperature of the wafer W obtained by being heated only by plasma without supplying backgas; t₂ is defined as a target temperature of the wafer W; and t₃ is defined as a temperature of the mounting table 10.

t₁>t₂>t₃

In an actual process for processing the wafer W, an initial temperature of the wafer W is detected by the temperature sensor at a time when the wafer W is loaded on the mounting table 10. In case where a target temperature of the wafer W is lower than the initial temperature thereof, the wafer W should be cooled down to the target temperature via the mounting table 10. In a such case, the valve 16B of the Ar feed source 16 is closed while the valve 15C of the He feed source 15 is opened, so that only the He gas of a high thermal conductivity is supplied. As a result, the thermal conductivity at the backside of the wafer W is increased. Therefore, heat conduction from the wafer W to the mounting table 10 is augmented, and thus the wafer W can rapidly reach the target temperature.

On the other hand, in case where the target temperature of the wafer W is higher than the initial temperature thereof, a cooling capability of the mounting table 10 needs to be limited in order to rapidly raise the temperature of the wafer W to the target temperature. In this case, the valve 15B of the He feed source 15 is closed while the valve 16B of the Ar feed source 16 is opened, so that only the Ar gas of a low thermal conductivity is supplied. As a result, a thermal conductivity on the surface of the wafer W is reduced, so that the wafer W can reach the target temperature rapidly. Alternatively, by way of making a virtual thermal insulation condition without supplying the Ar gas, the target temperature of the wafer W can also be obtained rapidly.

After the wafer W reaches a target temperature range, its temperature needs to be stabilized as a target temperature. For the stabilization of the target temperature, for example, three methods using different reference flow ratios and pressure ratios are employed. A first method is to set a reference flow ratio and a reference pressure ratio such that the wafer W is maintained at a target temperature; a second method is to set a reference flow ratio and a reference pressure ratio such that the wafer W is maintained at a temperature lower than the target temperature; and a third method is to set a reference flow ratio and a reference pressure ratio such that the wafer W is maintained at a temperature slightly higher than the target temperature. In any case of the first to the third methods, the reference flow ratio and the reference pressure ratio of two gases involved are obtained in advance for each constant temperature, as mentioned above.

In case of the first method (for setting a reference flow ratio and a reference pressure ratio such that the wafer W is maintained at a target temperature), the He gas and the Ar gas are used jointly and the controller 21 controls flow rates and pressures of the two gases based on the reference flow ratio and the reference pressure ratio of the two gases previously registered therein. In other words, the temperature of the wafer W is controlled to be maintained at a target temperature by controlling the thermal conductivity of the complex thermally conductive gas between the wafer W and the electrostatic chuck 13. Specifically, the flow rates of He gas and Ar gas are individually controlled to become same as their corresponding reference flow rates by using the mass flow controllers 15A and 16A. Thereafter, reference pressures of the two gases after the completion of the flow rate control are individually detected by using the pressure detecting units 15C and 16C. The controller 21 controls opening and closing of the variable valves 19A and 20A based on the values detected by the pressure detecting units 15C and 16C such that the pressure ratio of the two gases becomes same as the reference pressure ratio. At this time, in case where the temperature of the wafer W deviates from the target temperature, the wafer temperature is adjusted to coincide with the target temperature by the controller 21, which increases or decreases the flow rates and the pressures of the two gases based on a value detected by the temperature sensor while maintaining the reference flow ratio and the reference pressure ratio of the two gases constant. By this operation, the temperature of the wafer W repeatedly changes by going up and down around the target temperature. An average of these varying temperature values of the wafer is the target temperature.

In case of the second method (for setting a reference flow ratio and a reference pressure ratio such that the temperature of the wafer W is maintained at a constant temperature slightly lower than a target temperature), the He gas and the Ar gas are used jointly and the controller 21 sets the temperature of the wafer W to be maintained at a constant temperature slightly lower than the target temperature by controlling a thermal conductivity of the complex thermally conductive gas between the wafer W and the electrostatic chuck 13 based on the reference flow ratio and the reference pressure ratio of the two gases previously registered in the controller 21. That is, flow rates of the He gas and the Ar gas are respectively controlled to become same as their corresponding reference flow rates by using the mass flow controllers 15A and 16A, and, then, reference pressures of the two gases after the completion of the flow control are individually detected by using the pressure detecting units 15C and 16C. The controller 21 controls opening and shutting of the variable valves 19A and 20A based on the values detected by the pressure detecting units 15C and 16C, thereby controlling the pressure ratio of the two gases to become same as the reference pressure ratio. At this time, in case where the temperature of the wafer is deviated from a predetermined control range to a temperature below the target temperature, the former is adjusted to coincide with the latter by the controller 21, which lowers the thermal conductivity by reducing the flow rate of only the He gas or setting it as zero (off) based on a value detected by the temperature sensor with reference to the reference flow ratio and the reference pressure ratio. Thereafter, the wafer temperature is controlled to approximate the target temperature by increasing and decreasing or turning on and off the flow rate of the He gas only to increase and decrease the thermal conductivity. By this operation, the temperature of the wafer W, which was initially set to be lower than the target temperature, increases first and then repeatedly rises and falls about the target temperature. An average of these temperature values of the wafer is the target temperature. Further, in the second method, the temperature of the wafer can also be controlled to become the target temperature by increasing and decreasing the flow rate of the Ar gas only on the basis of the reference flow ratio and the reference pressure ratio of the He gas and the Ar gas.

In case of the third method (for setting a reference flow ratio and a reference pressure ratio such that the temperature of the wafer W is maintained at a constant temperature slightly higher than a target temperature), the He gas and the Ar gas are used together and the controller 21 maintains the temperature of the wafer W at a constant temperature slightly higher than the target temperature by controlling a thermal conductivity of the complex thermally conductive gas between the wafer W and the electrostatic chuck 13 based on the reference flow ratio and the reference pressure ratio of the two gases which are previously registered in the controller 21. That is, flow rates of the He gas and the Ar gas are individually controlled to become same as their respective reference flow rates by using the mass flow controllers 15A and 16A, and, then, reference pressures of the two gases after the completion of the flow control are individually detected by using the pressure detecting units 15C and 16C. The controller 21 controls opening and shutting of the variable valves 19A and 20A based on the values detected by the pressure detecting units 15C and 16C, thereby controlling the pressure ratio of the two gases to become same as the reference pressure ratio. At this time, in case where the temperature of the wafer W is deviated from a predetermined control range to a temperature above the target temperature, the former is controlled to be lowered to coincide with the latter by the controller 21, which raises the thermal conductivity by increasing the flow rate of the He gas only based on a value detected by the temperature sensor with reference to the reference flow ratio and the reference pressure ratio. Thereafter, the wafer temperature is controlled to approach the target temperature by increasing and decreasing the flow rate of the He gas only to increase and decrease the thermal conductivity. By this operation, the temperature of the wafer W, which was initially set to be higher than the target temperature, decreases first and then repeatedly rises and falls around the target temperature. An average of these temperature values of the wafer is the target temperature. Further, in the third method, the temperature of the wafer can also be controlled to become the target temperature by increasing and decreasing or turning on and off the flow rate of the Ar gas only on the basis of the reference flow ratio and the reference pressure ratio of the He gas and the Ar gas.

In case of changing a target temperature to become close to the temperature of the mounting table 10, i.e., in case of decreasing the target temperature, a cooling capability by the mounting table 10 is enhanced by stopping the supply of the Ar gas while supplying the He gas only or by increasing the flow rate of the He gas. By this operation, the cooling capability by the mounting table 10 can be improved thereby allowing rapid lowering of the wafer temperature.

On the contrary, in case of changing a target temperature to be further away from the temperature of the mounting table 10, i.e., in case of increasing the target temperature, the cooling capability by the mounting table 10 is lowered by, while stopping the supply of the He gas, supplying only the Ar gas or even reducing the flow rate of the Ar gas or shutting off the Ar gas. By such operation, the cooling capability by the mounting table 10 is reduced thereby enabling the temperature of the wafer to increase in an expeditious manner.

In case of lowering a target temperature in the middle of a process for, e.g., step etching, the supply of the Ar gas is ceased and only the He gas is supplied, or, the flow rate of the He gas is increased. By such, the cooling capability by the mounting table 10 is enhanced, so that the wafer temperature can be rapidly lowered down to a next target temperature. On the contrary, in case of increasing a target temperature during the process, the supply of the He gas is stopped and then only the Ar gas is supplied, or, the flow rate of the Ar gas is decreased or reduced to zero. By such operation, the cooling capability by the mounting table 10 is reduced, so that the temperature of the wafer can be expeditiously increased to a next target temperature. If the wafer W reaches a predetermined temperature range with reference to the next target temperature, the temperature of the wafer W is controlled to approach the target temperature by using one of the first to the third methods as described above.

The timing for the initiation of the control of the He gas and the Ar gas for the wafer processing is determined, e.g., by the controller 21 based on the temperature of the wafer W detected by the temperature sensor.

In accordance with the preferred embodiment as described above, flow rates and pressures of the He gas and the Ar gas, which serve as backgases, are detected just before being mixed, so that supply amounts of the two gases and a mixture ratio thereof can be accurately obtained. By using those thus obtained, the thermal conductivity of the complex thermally conductive gas can be accurately and reliably controlled at each processing stage of the wafer W. For example, in an etching process, a groove shape can be precisely formed. Further, in accordance with the preferred embodiment, the thermal conductivity of the complex thermally conductive gas can be controlled by way of increasing or decreasing flow rates and pressures of the two gases individually based on a reference flow ratio and a reference pressure ratio of the He gas and the Ar gas. Thus, a temperature stability of the wafer W can be secured even in the case of processing the wafer, e.g., at a high temperature because Ar gas can be used instead of low-pressure He gas having a poor controllability. Further, in the case of changing the temperature of the wafer W during the process, rises or falls in the temperature of the wafer W can be rapidly achieved because a thermal conductivity of the backside of the wafer W can be readily increased or decreased by individually controlling the flow rates and the pressures of the He gas and the Ar gas. Therefore, in case of a step etching for forming a groove with a deep trench structure as shown in FIG. 5, exact control of the shape can be realized.

Further, the present invention is not limited to the preferred embodiment described above. Though the present invention has been described with respect to the temperature condition of t₁>t₂>t₃, the present invention can also be applied under the condition of t₁′<t₂<t₃ (t₁′ being an initial temperature of the wafer) in a device generating no plasma for example. Further, He gas of a high thermal conductivity and Ar gas of a low thermal conductivity are exemplified as thermally conductive gases in the preferred embodiment. However, an inert gas such as Xenon having no influence on the processing can also be used, if required. In addition, though an etching device using a high frequency power has been exemplified as a vacuum processing device in the embodiment, the present invention can also be applied to, for example, an etching device using microwave and so on and a film formation device. Further, a object to be processed is not limited to a wafer.

What is claimed is:

1. A vacuum processing method comprising the steps of:
mounting an object to be processed on a temperature-adjustable mounting table in a vacuum processing chamber;
supplying thermally conductive gases between the mounting table and the object to impart a thermal conductivity therebetween; and
performing a vacuum processing by controlling the object to be maintained at a target temperature,
wherein the gas supplying step includes the steps of:
individually discharging at least two species of thermally conductive gases of different thermal conductivities at respective flow rates from respective gas sources thereof;
individually detecting a pressure of each of the thermally conductive gases; and
individually controlling a feed flow rate of each of the thermally conductive gases based on the detected pressure.

2. The method of claim 1, wherein the step of individually controlling the feed flow rate has the step of directly controlling the feed flow rate of each of the thermally conductive gases emitted from the gas sources.

3. The method of claim 1, wherein the step of individually controlling the feed flow rate has the step of controlling a degree of openness of a valve installed at a gas pipe.

4. A vacuum processing method comprising the steps of:
mounting an object to be processed on a temperature-adjustable mounting table in a vacuum processing chamber;
supplying thermally conductive gases between the mounting table and the object to impart a thermal conductivity therebetween; and
performing a vacuum processing by controlling the object to be maintained at a target temperature,
wherein in the gas supply step,
at least two species of thermally conductive gases of different thermal conductivities are individually discharged from respective gas sources thereof;
a thermally conductive gas of a relatively higher thermal conductivity is supplied in case where the target temperature of the object is at a side of an initial temperature of the mounting table with respect to an initial temperature of the object; and
a thermally conductive gas of a relatively lower thermal conductivity is supplied or a supply of the thermally conductive gases are stopped in case where the target temperature of the object is at an opposite side of an initial temperature of the mounting table with respect to an initial temperature of the object.

5. A vacuum processing method comprising the steps of:
mounting an object to be processed on a temperature-adjustable mounting table in a vacuum processing chamber;
supplying thermally conductive gases between the mounting table and the object to impart a thermal conductivity therebetween; and
performing a vacuum processing by controlling the object to be maintained at a target temperature,
wherein, if the temperature of the object reaches the target temperature, the gas supply step includes the steps of:
individually discharging at least two species of thermally conductive gases of different thermal conductivities at respective flow rates from respective gas sources thereof;
individually detecting a pressure of each of the thermally conductive gas; and
individually controlling a feed flow rate of each of the thermally conductive gases based on the target temperature and the detected pressure.

6. The method of claim 5, wherein when the target temperature is changed in the step of individually controlling the feed flow rate, a flow rate of a thermally conductive gas of a relatively higher thermal conductivity among the thermally conductive gases is increased or turned on in case where the target temperature after change is at a side of a temperature of the mounting table with respect to the target temperature before change; and a flow rate of a thermally conductive gas of a relatively lower thermal conductivity among the thermally conductive gases is increased or turned on or a supply of the thermally conductive gases is ceased in case where the target temperature after change is at an opposite side of the temperature of the mounting table with respect to the target temperature before change.

7. The method of claim 5 further comprising the step of obtaining in advance a first reference flow ratio and a first reference pressure ratio of the thermally conductive gases when the object is maintained at the target temperature and
wherein the step of individually controlling the feed flow rate has the step of controlling a total feed amount of the thermally conductive gases while maintaining the first reference flow ratio and the first reference pressure ratio constant.

8. The method of claim 5 further comprising the step of obtaining in advance a second reference flow ratio and a second reference pressure ratio of the thermally conductive gases when the object is maintained at a constant temperature lower than the target temperature,
wherein the step of individually controlling the feed flow rate has the step of increasing and decreasing or turning on and off a flow rate of a thermally conductive gas of a relatively higher thermal conductivity among the thermally conductive gases based on the second reference flow ratio and the second reference pressure ratio.

9. The method of claim 5 further comprising the step of obtaining in advance a second reference flow ratio and a second reference pressure ratio of the thermally conductive gases when the object is maintained at a constant temperature lower than the target temperature,
wherein the step of individually controlling the feed flow rate has the step of increasing and decreasing or turning on and off a flow rate of a thermally conductive gas of a relatively lower thermal conductivity among the thermally conductive gases based on the second reference flow ratio and the second reference pressure ratio.

10. The method of claim 5 further comprising the step of obtaining in advance a third reference flow ratio and a third reference pressure ratio of the thermally conductive gases when the object is maintained at a constant temperature higher than the target temperature,
wherein the step of individually controlling the feed flow rate has the step of increasing and decreasing or turning on and off a flow rate of a thermally conductive gas of a relatively lower thermal conductivity among the thermally conductive gases based on the third reference flow ratio and the third reference pressure ratio.

11. The method of claim 5 further comprising the step of obtaining in advance a third reference flow ratio and a third reference pressure ratio of the thermally conductive gases when the object is maintained at a constant temperature higher than the target temperature,
wherein the step of individually controlling the feed flow rate has the step of increasing and decreasing or turning on and off a flow rate of a thermally conductive gas of a relatively higher thermal conductivity among the thermally conductive gases based on the third reference flow ratio and the third reference pressure ratio.

12. A vacuum processing apparatus comprising:
a vacuum processing chamber;
a temperature-adjustable mounting table installed in the vacuum processing chamber;
gas sources for respectively discharging at least two species of thermally conductive gases of different thermal conductivities at respective flow rates;
a gas channel for supplying the thermally conductive gases discharged from the gas sources between the mounting table and an object mounted thereon;
a pressure detecting unit for individually detecting a pressure of each of the thermally conductive gases in the gas channel; and
a controller for individually controlling a feed flow rate of each of the thermally conductive gases based on the pressure detected by the pressure detecting unit.
